(19) United States
(12) Patent Application Publication
(10) Pub. No.: US 2003/0086463 A1
(43) Pub. Date: May 8, 2003

(54) Long wavelength VCSEL having oxide-aperture and method for fabricating the same

(76) Inventors: Jae-Heon Shin, Taejon (KR); O-Kyun Kwon, Taejon (KR); Won-Seok Han, Taejon (KR); Young-Gu Ju, Taejon (KR); Byueng-Su Yoo, Taejon (KR)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/057,383

(22) Filed: Jan. 23, 2002

(30) Foreign Application Priority Data
Nov. 8, 2001 (KR) 01-69489

(51) Int. Cl. H01S 5/00

(52) U.S. Cl. 372/46

(57) ABSTRACT

A long-wavelength VCSEL is provided. The laser includes a first conductive semiconductor substrate, lower mirror layers that are formed on the semiconductor substrate and are proper to the Bregg-reflection, an active layer formed on the lower mirror layer, a current passage layer that is formed on the active layer as a path through which an electric current flows into the active layer, current blocking layers that are formed on the active layer to encompass the current passage layer and limit the path through which an electric current flows into the active layer, an intra-cavity contact layer formed on a portion of the current passage layer and the current blocking layer, upper mirror layers that are formed on a portion of the intra-cavity contact layer and are proper to the Bragg-reflection, a first electrode formed on the exposed surface of the intra-cavity contact layer and the upper mirror layers, and a second electrode formed on a predetermined surface of the semiconductor substrate

### BACKGROUND OF THE INVENTION

1. Field of the Invention

The present invention relates to a vertical-cavity surface-emitting laser (VCSEL) and a method for fabricating the same, and more particularly, to such a laser having an oxide aperture and a method for fabricating the same.

2. Description of the Related Art

In general, a vertical-cavity surface-emitting laser (VCSEL) is a laser in which circular laser beam is emitted vertically from the surface of a substrate. The VCSEL can be efficiently coupled into devices or optical fibers, and it is suitable for wafer-level testing, thereby reducing the manufacturing costs during the mass production thereof.

Due to the above merits, there have recently been a lot of researches into the use of the VCSEL having frequency of 1.55 μm as light source that is required in the middle or long-distance communication. As a result, a column-shaped VCSEL, an ion-injection VCSEL, a side-etched VCSEL and a hetero-junction distributed Bragg reflector(DBR)-type VCSEL have been suggested.

To fabricate the column-shaped VCSEL, a multi-layered structure in which a lower DBR mirror layer, an active layer and an upper DBR mirror layer are sequentially stacked, is formed. Then, the multi-layered structure is etched by anisotrophical mesa etching so that the upper DBR mirror layer and the active layer may conform to a column shape. The column-shaped VCSEL is advantageous in that it is easy to fabricate, and the diffusion of an electric current is not caused therein. However, heat is extremely generated, and the threshold current is larger and is oscillated into multi-crossing mode.

The ion-injection VCSEL is made by injecting high-energy protons, and destroying only crystals in a region in which the protons have been injected, so that an electric current flow into a region in which protons have not been injected. If In the case that the upper DBR mirror layer is formed very thickly to generate long-wavelength laser beam, protons having considerably high energy must be injected into the upper DBR mirror layer. However, it is difficult to find out material for a mask layer that is used as ion implantation mask layer. Also, it is impossible to manufacture small-sized devices because the border of an induction aperture defined by protons bombardment is not clear, and the threshold current is high. Further, if material for the upper DBR mirror layer is formed of an InAlGaAs-based material having low heat conductivity, this laser is not continuously oscillated at the room temperature, due to low thermal emission.

The side-etching VCSEL is fabricated by etching the sides of the active layer, which constitutes for the structure of the column-shaped VCSEL, to a predetermined depth. This laser is advantageous in that it has low threshold currents and the better mode characteristics because of the flow of an electric current only along the center of the laser. However, this laser is not mechanically stable and does not emit heat smoothly due to the hollow sides of the active layer.

The hetero-junction DBR-type VCSEL is fabricated by a substrate attaching method or a metamorphic growing method if an upper mirror layer is formed of an AlGaAs-based material, whereas high-efficient long-wavelength VCSEL is fabricated by an ion implantation method and oxide layer formation method, which are well-known methods, as the VCSEL of 850 nm. The substrate attaching method and the metamorphic growing method are not well known, have low yield and are not reliable. Particularly, the metamorphic growing method uses only molecular beam epitaxy (MBE) that is not suitable for mass production as compared to metal-organic chemical-vapor deposition (MOCVD).

Accordingly, there is a need for a long-wavelength VCSEL that can be fabricated by carrying out an epitaxial growth method at a time, has a thick cavity contact layer for easy thermal emission, and has a mechanically stable structure into which an electric current is efficiently injected, and a method for fabricating the same.

### SUMMARY OF THE INVENTION

To solve the above problems, it is a first objective of the present invention to provide a long-wavelength vertical-cavity surface-emitting laser (VCSEL) having an oxide aperture.

It is a second objective of the present invention to provide a method for fabricating a long-wavelength VCSEL according to the present invention.

To achieve the first objective, there is provided a long-wavelength VCSEL. This laser includes a first conductive semiconductor substrate; lower mirror layers being formed on the semiconductor substrate and being proper to the Bragg-reflection; an active layer being formed on the lower mirror layer; a current passage layer being formed on the active layer and being a path through which an electric current flows into the active layer; current blocking layers being formed on the active layer to encompass the current passage layer, the current blocking layers for limiting the path through which an electric current flows into the active layer; an intra-cavity contact layer being formed on the current passage layer and the current blocking layer; upper mirror layers being formed on a portion of the intra-cavity contact layer and being proper to the Bragg-reflection; a first electrode being formed on an exposed surface of the intra-cavity contact layer and the surface of the upper mirror layers; and a second electrode being formed on a portion of the semiconductor substrate.

Preferably, the upper mirror layer has a first mesa structure of a first width, and the current blocking layers, the current passage layer and the intra-cavity contact layer have second mesa structures of a second width that is larger than the first width.

Preferably, the lower mirror layer and the second electrode are doped with first conductive materials that are the same material of the semiconductor substrate, and the intra-cavity contact layer and the first electrode are doped with a second conductive material that is not the same material of the semiconductor substrate

Preferably, the upper mirror layer is not doped with any material.

Preferably, the current passage layer is an InAlAs bulk layer and the current blocking layer is an InAlAs oxide layer.

Preferably, the first electrode is an Au electrode having a thickness of 5000 Å or more.

To accomplish the second objective, there is provided a method of fabricating a long-wavelength VCSEL. In the method, a lower mirror layer, an active layer, a first semiconductor layer, an intra-cavity contact layer and an upper mirror layer are sequentially formed on a first conductive semiconductor substrate; a first etching process having a first mask layer pattern is performed as an etching mask, so that the upper mirror layer has a first mesa structure of a first width; a second mask layer pattern is formed on the intra-cavity contact layer and upper mirror layer, portions of which are exposed during the first etching process; a second etching process having the second mask layer pattern is performed as an etching mask, so that the first semiconductor layer and the intra-cavity contact layer have a second mesa structure of a second width to be larger than the first width; an oxidation process is performed to oxidize the sides of the first semiconductor layer, so that a current passage layer is formed between the active layer and the intra-cavity contact layer and a current blocking layer is formed to encompass the current passage layer; the second mask layer pattern is removed; a first electrode is formed on the intra-cavity contact layer and the upper mirror layer; and a second electrode is formed on a predetermined portion of the semiconductor substrate.

Preferably, the semiconductor substrate is formed of an InP substrate, the lower and upper mirror layers are formed of multi-layered thin layers of InAlGaAs/InAlAs, InAlGaAs/InP or GaAsSb/AlAsSb, the active layer is formed of a InGaAs or InGaAsP quantum well, and the first semiconductor layer is formed of an InAlAs bulk layer.

Preferably, the second mask layer pattern is formed of a silicon nitride layer.

Preferably, the second width of the second mesa structure is 1.8 or 3.5 times as wide as the first width of the first mesa structure.

Preferably, the first and second etching processes are performed by dry etching.

Preferably, the oxidation process is performed at 450-550° C. under vapor atmosphere

Preferably, after the first etching process, wet etching is performed to remove the upper mirror layer remaining on the intra-cavity contact layer.

### BRIEF DESCRIPTION OF THE DRAWINGS

The above objectives and advantages of the present invention will become more apparent by describing in detail a preferred embodiment thereof with reference to the attached drawings in which:

FIG. 1 is a cross-sectional view of a long-wavelength vertical-cavity surface-emitting laser (VCSEL) having an oxide aperture according to the present invention; and

FIGS. 2 through 5 are cross-sectional views for explaining a method for fabricating a long-wavelength VCSEL according to the present invention.

### DETAILED DESCRIPTION OF THE INVENTION

The present invention will now been described more fully with reference to the accompanying drawings, in which a preferred embodiment of the invention is shown. This invention may, however, be embodied in many different forms and should not be construed as being limited to the embodiment set forth herein; rather, this embodiment is provided so that this disclosure will be thorough and complete, and will fully convey the concept of the invention to those skilled in the art. The reference numerals in different drawings represent the same elements, and thus their description will be omitted.

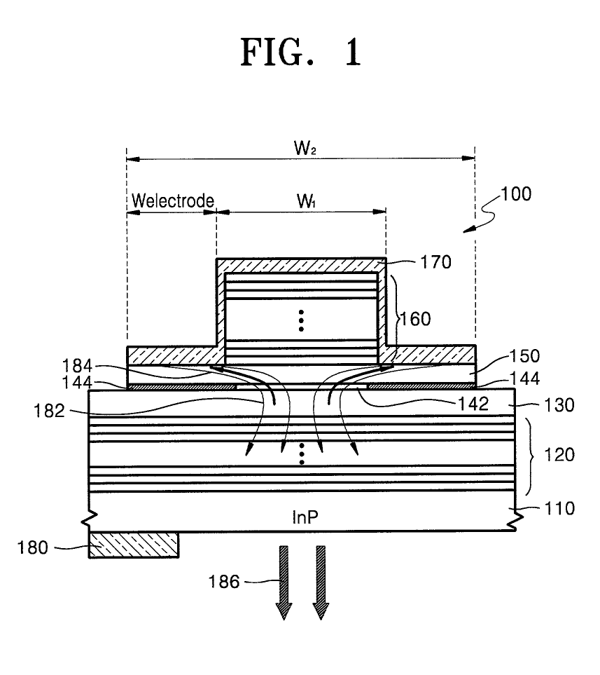

FIG. 1 is a cross-sectional view of a long-wavelength vertical-cavity surface-emitting laser (VCSEL) 100 having an oxide aperture according to the present invention. Referring to FIG. 1, the long-wavelength VCSEL 100 is formed on an n-type InP substrate 110. In detail, an n-type lower mirror layers 120 that are proper to the Bragg-reflection, and an active layer 130 that is used to cause an optical gain in oscillated laser beam, are sequentially formed on the n-type InP substrate 110. A current passage layer 142 and a current blocking layers 144 are formed on a portion of the surface of the active layer 130. The current blocking layers 144 is formed to encompass the current passage layer 142, and may be circle, square or polygon-shaped although not illustrated in the drawings. A p-type intra-cavity contact layer 150, which is used as a current flowing passage and a thermal emission passage, is formed on the current passage layer 142 and the current blocking layers 144. Undoped upper mirror layers 160 are formed on a portion of the surface of the p-type intra-cavity contact layer 150, and then, a p-type electrode 170 is formed on the p-type intra-cavity contact layer 150 and the upper mirror layers 160. An n-type electrode 180 is formed on a portion of the bottom of the n-type InP substrate 110.

The upper mirror layers 160 have a first mesa structure having a first width W₁, and the intra-cavity contact layer 150 and the current blocking layers have a second mesa structure of a second width W₂. The second width W₂ of the second mesa structure is about 1.8 or 3.5 times as wide as the first mesa structure of the first width W₁.

Each of the n-type lower mirror layers 120 and the upper mirror layers 160 may be formed of a multi-layered thin layer of InAlGaAs/InAlAs, InAlGaAs/InP or GaAsSb/AlAsSb that is proper to the Bragg-reflection. The multi-layered thin layer of InAlGaAs/InAlAs has merits that it has large refractive index, can be matched with the InP substrate 110, and stably controls the flow of gas that is grown with analogous gas, e.g., an V-based element. The multi-layered thin layer of InAlGaAs/InP is not formed of regular V-based elements, but has larger refractive index than the multi-layered thin layer of InAlGaAs/InAlAs, and has high thermal conductivity. The refractive index of a multi-layered thin layer of GaAsSb/AlAsSb is twice as high as that of the multi-layered thin layer of InAlGaAs/InAlAs. Preferably, the n-type lower mirror layers 120 and the upper mirror layers 160 are about forty-two pairs of multi-layered thin layers if they are formed of the multi-layered thin layer of InAlGaAs/InAlAs. In this case, the n-type lower mirror layers 120 and the upper mirror layers 160 have refractive index of approximately 99.6%.

The active layer 130 has a structure in which a clad layer, a multi-quantum well layer, and a clad layer are sequentially stacked. The multi-quantum well layer has a quantum well structure made of InGaAs or InGaAsP that includes long-wavelength, i.e., about 1.5-1.6 μm.

The current passage layer 142 and the current blocking layers 144 are formed of an InAlAs layer and InAlAs oxide layer, respectively. The current passage layer 142 may be lattice-matched with the InP substrate 110. In the case that the current passage layer 142 has a high Al content, the current passage layer 142 may be lattice-mismatched with the InP substrate 110. The current passage layer 142 is an oxide aperture encompassed by the current blocking layers 144 that is an oxide layer. The p-type intra-cavity contact layer 150 is a p-type semiconductor layer, for example, an InP layer.

The p-type electrode 170 is formed of an Au electrode of a thickness of about 5000 Å, so that the refractive index of the upper mirror layers 160 can increase and the p-type electrode 170 functions as a cooling pin.

Meanwhile, fine arrows 182, arrows 184 of moderate thickness and thick arrows 186 denote the path of the flow of an electric current, the path of the flow of emissive heat, and laser beam, respectively.

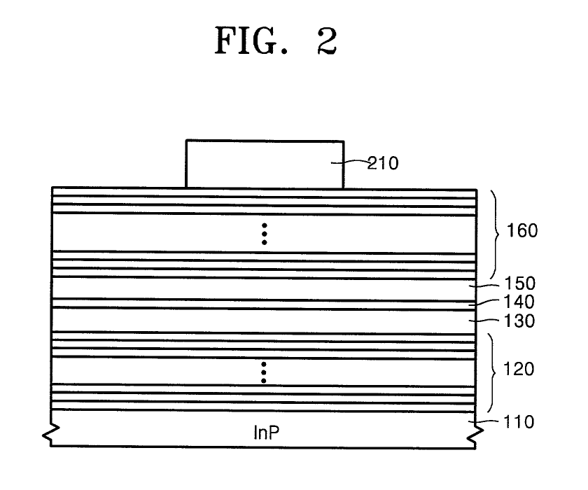

FIGS. 2 through 5 are cross-sectional views for explaining a method for fabricating a long-wavelength VCSEL.

Referring to FIG. 2, on an InP substrate 110 are sequentially stacked a n-type lower mirror layers 120 that is a multi-layered thin layer of InAlGaAs/InAlAs, an active layer 130, an InAlAs bulk layer 140, a p-type intra-cavity contact layer 150, and an undoped upper mirror layers 160. The n-type lower mirror layers 120 and the upper mirror layers 160 may be multi-layered thin layers of InAlGaAs/InP or GaAsSb/AlAsSb. The active layer 130 has a structure in which a clad layer, a multi-quantum well layer and a clad layer are sequentially stacked. In particular, the multi-quantum well layer is a quantum well structure of InGaAs or InGaAsP having long-wavelength of approximately 1.5-1.6 μm. The InAlAs bulk layer 140 is formed of a tense-strained InAlAs layer that has a large content of Al for the speedy oxidation during a subsequent oxidation process. The p-type intra-cavity contact layer 150 is formed of a p-type semiconductor layer, e.g., an InP layer.

After the growth of the upper mirror layers 160, a first mask layer pattern 210 is formed on the surface of the uppermost layer of the upper mirror layers 160 to expose a portion of the upper mirror layers 160. The first mask layer pattern 210 may be formed of a silicon oxide layer, a photoresist layer or a titanium oxide layer.

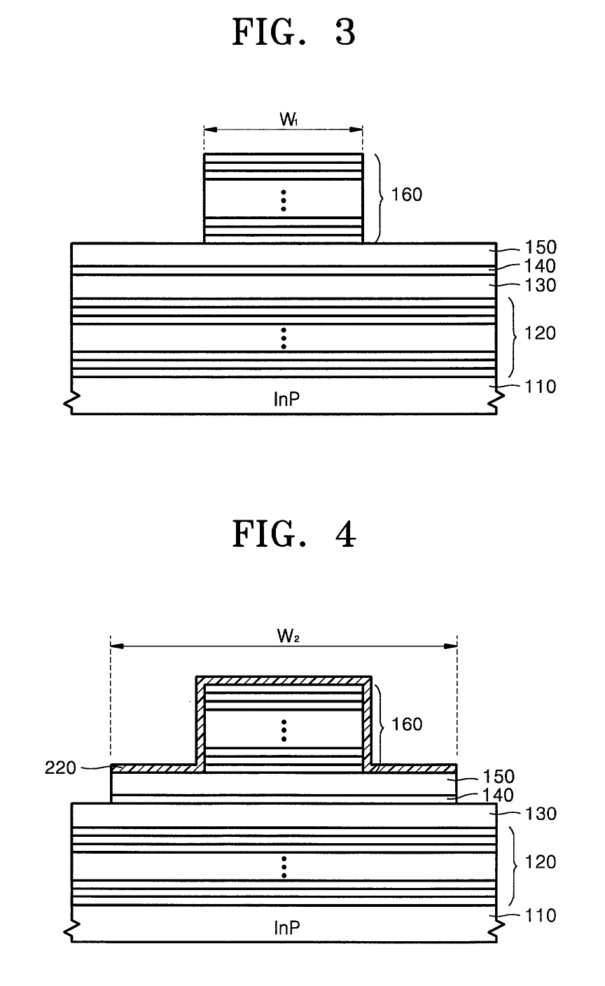

Thereafter, as shown in FIG. 3, a first etching process is carried out with the first mask layer pattern 210 of FIG. 2 as an etching mask, so that the upper mirror layers 160 have a first mesa structure having a first width W₁. The first etching process is performed by dry etching, for example, reactive ion etching (RIE) or reactive ion beam etching (RIBE). At this time, a Cl₂/Ar-based ion is used as etching ion. During the first etching process, portions of the upper mirror layers 160 are etched to completely expose the intra-cavity contact layer 150 by a method of monitoring the thickness of the upper mirror layers 160. The first mask layer pattern 210 may be circular, square or polygonal shaped, and thus, the upper mirror layers 160 having a mesa structure may be also circular, square or polygonal shaped.

After the first etching process, a second etching process is performed to completely remove the upper mirror layers 160 remaining on the intra-cavity contact layer 150. The second etching process is carried out by wet etching that uses an etching solution having better etching selectivity with respect to the intra-cavity contact layer 150. For instance, the upper mirror layers 160 are formed of InAlGaAs-based material, the intra-cavity contact layer 150 is formed of InP-based material, and the etching solution is used with a mixing solution of H₃PO₄, H₂O₂, and H₂O.

Next, referring to FIG. 4, a protective layer 220 is formed to cover the upper mirror layers 160 and some portions of the intra-cavity contact layer 150. The protective layer 220 may be formed of a silicon nitride (SiNₓ) layer. With the protective layer 220 as an etching mask, a third etching process is then performed to make the intra-cavity contact layer 150 and the InAlAs bulk layer 140 have a second mesa structure having a second width W₂. The third etching process is performed using dry etching such as reactive ion etching, during which the intra-cavity contact layer 150 and the InAlAs bulk layer 140 are etched with Cl₂/Ar-based ion until the active layer 130 is exposed. The protective layer 220 may be circular, square or polygonal shaped, and thus, the mesa-structured intra-cavity contact layer 150 and InAlAs bulk layer 140 may be also circular, square or polygonal shaped.

The size of an oxide aperture, which is to be formed during a subsequent process, i.e., the size of a current passage layer defined by current blocking layers, is related to the first width W₁ of the upper mirror layers 160 and the second width W₂ of the intra-cavity contact layer 150 and the InAlAs bulk layer 140. A detailed description thereof will be provided later.

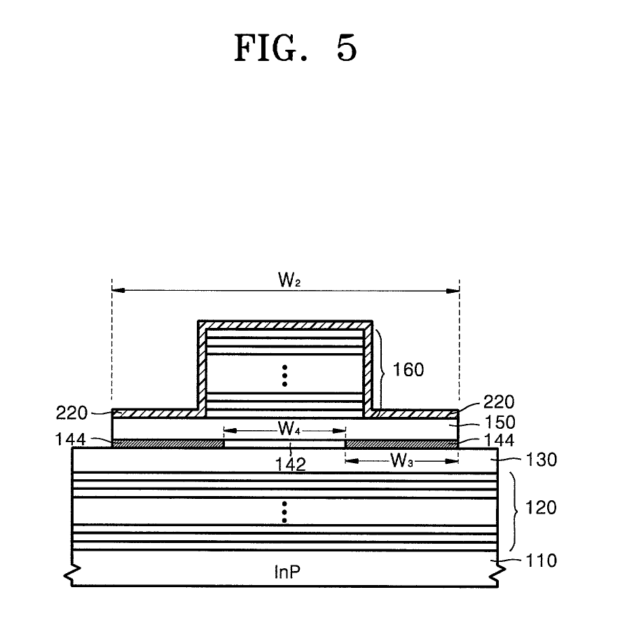

Thereafter, as shown in FIG. 5, an oxidation process is carried out to oxidize portions of the sides of the InAlAs bulk layer 140. The oxidation process is performed under vapor atmosphere at 450-550° C. In this case, the inflow of vapor is carried out by passing nitrogen gas, which is used as a carrier gas, through a container in which water of 60-90° C. is put. That is, nitrogen gas, which passes through the container, flows together with vapor into a furnace. Preferably, the inflow rate of the nitrogen gas, which is a carrier gas, is 0.1-10 liter/minute, but is not limited. After the oxidation process, a current passage layer 142, which is an InAlAs bulk layer, is deposited at the center of the active layer 130, and current blocking layers 144, which are InAlAs oxide layers, are deposited along the edges of the active layer 130 to encompass the current passage layer 142.

Once the current passage layer 142 and the current blocking layers 144 are formed, the protective layer 220 is removed. Then, as shown in FIG. 1, a p-type electrode, e.g., an Au electrode, is formed on the intra-cavity contact layer 150 and the upper mirror layers 160, and an n-type electrode 180 is formed on a portion of the bottom of the InP surface 110.

Meanwhile, the first width W₁ of the upper mirror layers 160, which have the first mesa structure, must be slightly larger than the width of the current passage layer 142 of FIG. 5 for the effective thermal emission. For example, preferably, the first width W₁ of the upper mirror layers 160 is approximately 12 μm if the width of the current passage layer 142 is 10 μm. That is, it would be better to allow the leeway of 2 μm, which is the difference between the first width W₁ and the width of the current passage layer 142, taking into account of the aberration made during a photo process. However, in the case of precise photo process, the leeway can be reduced.

The second width W₂ of the intra-cavity contact layer 150 and InAlAs bulk layer 140 of FIG. 4 is determined by the width of the p-type electrode 170 of FIG. 1, which is to be formed on the intra-cavity contact layer 150. In the case that the width of the p-type electrode 170 is smaller than the first width W₁ of the upper mirror layers 160, an electric current cannot be regularly injected and further, thermal emission is not easy. For this reason, it is preferable that the width of the p-type electrode 170 is at least 0.5 times as wide as the first width W₁ of the upper mirror layers 160 having the first mesa structure. However, if the width of the p-type electrode 170 is extremely larger, a lot of time will be required during an oxidation process. For instance, although the oxidation process is performed at high temperature, e.g., 500° C., the amount of oxidation is just 1-2 μm/hour. That is, the speed of the oxidation is comparatively very slow. Thus, preferably, the width of the p-type electrode 170 is 0.5-0.7 times as wide as the first width W₁ when the first width W₁ is 12 μm, i.e., approximately 6-8 μm.

If the width of the p-type electrode 170 is determined, the second width W₂ of the intra-cavity contact layer 150 and InAlAs bulk layer 140 is calculated as follows:

W₂=W₁+2(W_{process}+W_{electrode}) (1)

wherein W₂ denotes the width of the second mesa structure, W₁ denotes the width of the first mesa structure, W_{process} denotes the aberration of process, and the W_{electrode} denotes the width of the p-type electrode 170 of FIG. 1. For example, the width W₂ of the second mesa structure is 30 μm when the width W₁ of the first mesa structure is 12 μm, the aberration of process W_{process} is 2 μm and the width of the p-type electrode W_{electrode} is 7 μm.

After the determination of the width W₂ of the second mesa structure, the width W₃ of the current blocking layers 144 of FIG. 5, which is formed during the oxidation process, is calculated as follows:

$${W}_{3} = \frac{{W}_{2} - {W}_{4}}{2} \qquad ( 2 )$$

wherein W₃ denotes the width of the current blocking layers 144, W₂ denotes the width of the second mesa structure, and W₄ denotes the width of the current passage layer 142, which becomes an oxide aperture. For example, when the width W₂ of the second mesa structure is 30 μm and the width W₄ of the current passage layer 142 is 10 μm, the width W₃ of the current blocking layers 144, which is the depth to be oxidized during the oxidation process, becomes 10 μm.

As described above, in a long-wavelength VCSEL and a method for fabricating the same, according to the present invention, a current passage layer of InAlAs, which is an oxide aperture, is defined by InAlAs oxide layers, which are current blocking layers, thereby minimizing a loss in an electric current and an electric charge. At the same time, the proper width of each of first and second mesa structures can be determined for the effective thermal emission. Further, a long-wavelength VCSEL according to the present invention can be fabricated by the prior art techniques.

What is claimed is:

1. A long-wavelength VCSEL comprising:
a first conductive semiconductor substrate;
lower mirror layers being formed on the semiconductor substrate and being proper to the Bregg-reflection;
an active layer being formed on the lower mirror layer;
a current passage layer being formed on the active layer and being a path through which an electric current flows into the active layer;
current blocking layers being formed on the active layer to encompass the current passage layer, the current blocking layers for limiting the path through which an electric current flows into the active layer;
an intra-cavity contact layer being formed on the current passage layer and the current blocking layer;
upper mirror layers being formed on a portion of the intra-cavity contact layer and being proper to the reflection-reflection;
a first electrode being formed on an exposed surface of the intra-cavity contact layer and the surface of the upper mirror layers; and
a second electrode being formed on a portion of the semiconductor substrate.

2. The VCSEL of claim 1, wherein the upper mirror layer has a first mesa structure of a first width, and the current blocking layers, the current passage layer and the intra-cavity contact layer have second mesa structures of a second width that is larger than the first width.

3. The VCSEL of claim 1, wherein the lower mirror layer and the second electrode are doped with first conductive materials that are the same material of the semiconductor substrate, and the intra-cavity contact layer and the first electrode are doped with a second conductive material that is not the same material of the semiconductor substrate.

4. The VCSEL of claim 1, wherein the upper mirror layer is not doped with any material.

5. The VCSEL of claim 1, wherein the current passage layer is an InAlAs bulk layer and the current blocking layer is an InAlAs oxide layer.

6. The VCSEL of claim 1, wherein the first electrode is an Au electrode having a thickness of 5000 Å or more.

7. A method of fabricating a long-wavelength VCSEL comprising:
sequentially forming a lower mirror layer, an active layer, a first semiconductor layer, an intra-cavity contact layer and an upper mirror layer on a first conductive semiconductor substrate;
performing a first etching process having a first mask layer pattern as an etching mask, so that the upper mirror layer has a first mesa structure of a first width;
forming a second mask layer pattern on the intra-cavity contact layer and upper mirror layer, portions of which are exposed during the first etching process;
performing a second etching process having the second mask layer pattern as an etching mask, so that the first semiconductor layer and the intra-cavity contact layer have a second mesa structure of a second width to be larger than the first width;
performing an oxidation process to oxidize the sides of the first semiconductor layer, so that a current passage layer is formed between the active layer and the intra-cavity contact layer and a current blocking layer is formed to encompass the current passage layer;
removing the second mask layer pattern;
forming a first electrode on the intra-cavity contact layer and the upper mirror layer; and
forming a second electrode on a predetermined portion of the semiconductor substrate.

8. The method of claim 7, wherein the semiconductor substrate is formed of an InP substrate, the lower and upper mirror layers are formed of multi-layered thin layers of InAlGaAs/InAlAs, InAlGaAs/InP or GaAsSb/AlAsSb, the active layer is formed of a InGaAs or InGaAsP quantum well, and the first semiconductor layer is formed of an InAlAs bulk layer.

9. The method of claim 8, wherein the first semiconductor layer is formed of a tension-strained InAlAs bulk layer in which the content of Aluminium is greater than the content of Indium and thus, is lattice-mismatched with respect to InP.

10. The method of claim 10, wherein the second mask layer pattern is formed of a silicon nitride layer.

11. The method of claim 7, wherein the second width of the second mesa structure is 1.8 or 3.5 times as wide as the first width of the first mesa structure.

12. The method of claim 7, wherein the first and second etching processes are performed by dry etching.

13. The method of claim 7, wherein the oxidation process is performed at 450-550° C. under vapor atmosphere.

14. The method of claim 7 further comprising after the first etching process, wet etching is performed to remove the upper mirror layer remaining on the intra-cavity contact layer.
